(19) United States
(12) Patent Application Publication
(10) Pub. No.: US 2026/0231126 A1
(43) Pub. Date: Aug. 6, 2026

(54) DEVICE TO READER FREQUENCY MULTIPLEXING WITH MANCHESTER ENCODING

(71) Applicant: InterDigital Patent Holdings, Inc., Wilmington, DE (US)

(72) Inventors: Erdem Bala, East Meadow, NY (US); Kevin Wanuga, Souderton, PA (US); Senay Negusse, Montreal (CA); Martino Freda, Laval (CA); Jongwoo Hong, New York, NY (US)

(73) Assignee: InterDigital Patent Holdings, Inc., Wilmington, DE (US)

(21) Appl. No.: 19/044,311

(22) Filed: Feb. 3, 2025

(51) Int. Cl. H04W 72/0453; H03M 5/12; H04L 27/12

(52) U.S. Cl. CPC H04W 72/0453; H03M 5/12; H04L 27/12

(57) ABSTRACT

A wireless transmit/receive unit (WTRU) transmits a message including resource allocation configuration information. The resource allocation configuration information includes: scaling factors, and a respective set of square wave clock cycles associated with each of the scaling factors. The WTRU transmits a reader-to-device (R2D) preamble indicating a first square wave clock cycle. The WTRU transmits control information indicating a first scaling factor of the scaling factors. The WTRU monitors for reception of device-to-reader (D2R) preambles. The WTRU determines, based on a received D2R preamble, a second square wave clock cycle from the set of square wave clock cycles associated with the indicated first scaling factor and first square wave clock cycle. The WTRU monitors for D2R transmissions based on the determined second square wave clock cycle. The WTRU transmits information indicating successful reception of the D2R transmissions based on the determined second square wave clock cycle.

### BACKGROUND

The 3^{rd} Generation Partnership Project (3GPP) has recently started studying ambient Internet of Things (IoT) (AIoT). The devices that are in the scope of the study may have power consumption of about 1 μW to a few hundreds of μW. The devices may transmit using backscattering.

In backscattering, a device reflects a received radio frequency (RF) signal after modulating the signal using a baseband signal. Baseband physical layer processing may use line codes for digital baseband modulation. In a line code, digital bits are encoded into one or a sequence of pulses. For example, bit 1 may be encoded as a pulse with level +A and bit 0 may be encoded as a pulse of level 0. Overall, A=1 is assumed without loss of generality. In another example, bit 1 may be encoded as a pulse with level +A and bit 0 may be encoded as a pulse of level −A. In yet another example, bit 1 may be encoded as a half-pulse with level 0 (or −A) followed by a half-pulse with level A and bit 0 may be encoded as a half-pulse with level +A followed by a half-pulse with level 0 (or −A). This last encoding scheme is known as Manchester encoding.

An IoT device may use backscatter modulation to transmit data to a receiver. In backscattering, a device does not generate an RF carrier but receives it from an external source and reflects the received RF signal. The baseband signal may be modulated on the reflected RF carrier. This may be achieved by using the impedance mismatch concept. An antenna impedance may be connected to a load impedance at the device. By changing the reflection coefficient (by adjusting the load impedance) over time, the amplitude, frequency, etc. of the reflected signal may be changed. For example, ON-OFF keying modulation may be achieved by using (non-reflecting state/OFF signal) or (reflecting state/ON signal). A commonly used radio frequency identification (RFID) specification is based on backscatter communications wherein RFID tags switch the reflection coefficient between two states based on the data being sent. Amplitude-shift keying (ASK) and phase-shift keying (PSK) are supported by the RFID tags.

The spectrum of a line encoded signal may be shifted in frequency. This may be used for example to multiplex multiple device-to-reader (D2R) transmissions within the same channel wherein each of the multiplexed D2R transmissions may occupy different spectral resources in the channel.

### SUMMARY

Apparatus and methods of frequency multiplexing with Manchester encoding are disclosed herein. In an example, a wireless transmit/receive unit (WTRU) transmits a message including resource allocation configuration information. In an example, the resource allocation configuration information includes: one or more scaling factors, and a respective set of square wave clock cycles associated with each of the one or more scaling factors. Further, the WTRU transmits a reader-to-device (R2D) preamble indicating a first square wave clock cycle. Also, the WTRU transmits control information indicating a first scaling factor of the one or more scaling factors. Further, the WTRU monitors for reception of one or more device-to-reader (D2R) preambles. Additionally, the WTRU determines, based on a received D2R preamble, a second square wave clock cycle from the set of square wave clock cycles associated with the indicated first scaling factor and first square wave clock cycle. Also, the WTRU monitors for one or more D2R transmissions based on the determined second square wave clock cycle. Moreover, the WTRU transmits information indicating successful reception of the one or more D2R transmissions based on the determined second square wave clock cycle.

In an example, the second square wave clock cycle is a devise-selected second square wave clock cycle. Additionally or alternatively, the R2D preamble is transmitted to a device. Additionally or alternatively, the device is an ambient Internet-of-Things (AIoT) device. Additionally or alternatively, the WTRU is a WTRU reader. Additionally or alternatively, the resource allocation configuration information further includes support for one or more types of frequency shifts.

Additionally or alternatively, a device-selected type of small frequency shift is determined based on the received D2R preamble. Additionally or alternatively, a number of times a device is expected to transmit or repeat a Manchester codeword in one bit duration is determined based on the number of clock cycle durations in a bit duration of a square wave clock cycle.

Additionally or alternatively, the monitoring for the one or more D2R transmissions is determined further based on a type of small frequency shift of the received D2R preamble. Additionally or alternatively, the resource allocation configuration information includes a second scaling factor of the one or more scaling factors.

### BRIEF DESCRIPTION OF THE DRAWINGS

A more detailed understanding may be had from the following description, given by way of example in conjunction with the accompanying drawings, wherein like reference numerals in the figures indicate like elements, and wherein:

FIG. 1A is a system diagram illustrating an example communications system in which one or more disclosed embodiments may be implemented;

FIG. 1B is a system diagram illustrating an example wireless transmit/receive unit (WTRU) that may be used within the communications system illustrated in FIG. 1A according to an embodiment;

FIG. 1C is a system diagram illustrating an example radio access network (RAN) and an example core network (CN) that may be used within the communications system illustrated in FIG. 1A according to an embodiment;

FIG. 1D is a system diagram illustrating a further example RAN and a further example CN that may be used within the communications system illustrated in FIG. 1A according to an embodiment;

FIG. 2 is a transmission diagram illustrating examples of frequency shift methods;

FIG. 3 is a signaling diagram illustrating an example of a random access procedure for an ambient Internet of Things (AIoT) device;

FIG. 4 is a signaling diagram illustrating an example of a radio frequency identification (RFID) inventory procedure;

FIG. 5 is a transmission diagram illustrating an example of backscattering modulation;

FIG. 6 is a transmission diagram illustrating an example of power spectral density of Manchester encoding with sixty-four (64) sample chips;

FIG. 7 is a transmission diagram illustrating an example of power spectral density of Manchester encoding with eight (8) sample chips;

FIG. 8 is a transmission diagram illustrating an example of functional relations for D2R chip rate, line code rate, and small frequency shift rates as indicated in R2D control information; and

FIG. 9 is a flowchart diagram illustrating a procedure of frequency multiplexing with Manchester encoding.

### DETAILED DESCRIPTION

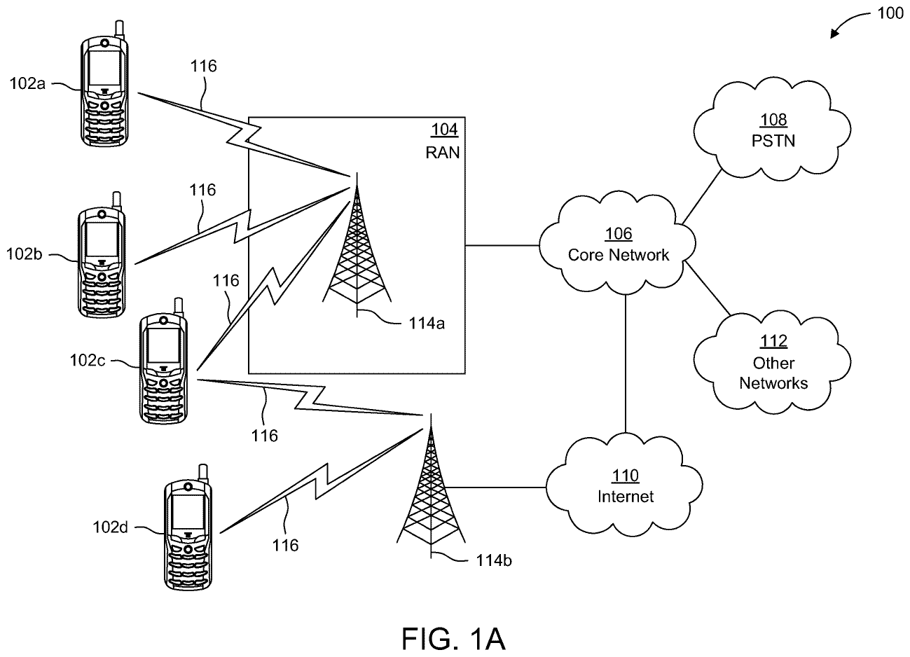

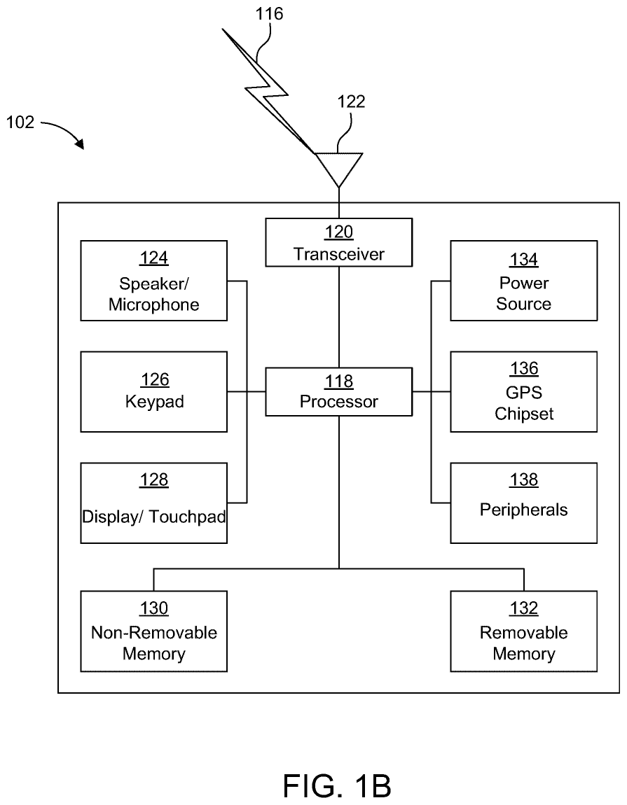

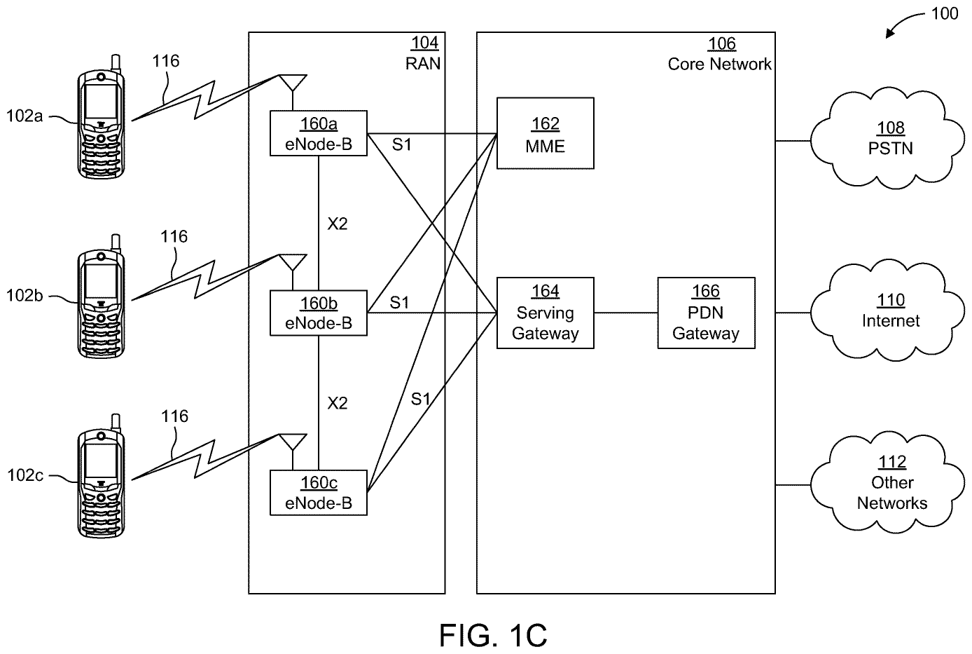

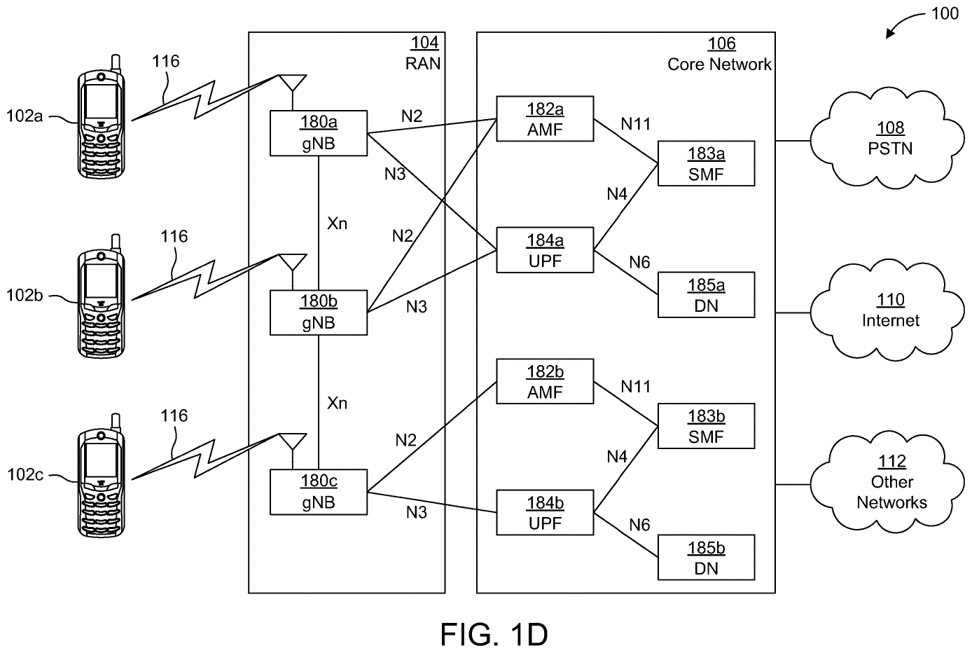

FIG. 1A is a diagram illustrating an example communications system 100 in which one or more disclosed embodiments may be implemented. The communications system 100 may be a multiple access system that provides content, such as voice, data, video, messaging, broadcast, etc., to multiple wireless users. The communications system 100 may enable multiple wireless users to access such content through the sharing of system resources, including wireless bandwidth. For example, the communications systems 100 may employ one or more channel access methods, such as code division multiple access (CDMA), time division multiple access (TDMA), frequency division multiple access (FDMA), orthogonal FDMA (OFDMA), single-carrier FDMA (SC-FDMA), zero-tail unique-word discrete Fourier transform Spread OFDM (ZT-UW-DFT-S-OFDM), unique word OFDM (UW-OFDM), resource block-filtered OFDM, filter bank multicarrier (FBMC), and the like.

As shown in FIG. 1A, the communications system 100 may include wireless transmit/receive units (WTRUs) 102a, 102b, 102c, 102d, a radio access network (RAN) 104, a core network (CN) 106, a public switched telephone network (PSTN) 108, the Internet 110, and other networks 112, though it will be appreciated that the disclosed embodiments contemplate any number of WTRUs, base stations, networks, and/or network elements. Each of the WTRUs 102a, 102b, 102c, 102d may be any type of device configured to operate and/or communicate in a wireless environment. By way of example, the WTRUs 102a, 102b, 102c, 102d, any of which may be referred to as a station (STA), may be configured to transmit and/or receive wireless signals and may include a user equipment (UE), a mobile station, a fixed or mobile subscriber unit, a subscription-based unit, a pager, a cellular telephone, a personal digital assistant (PDA), a smartphone, a laptop, a netbook, a personal computer, a wireless sensor, a hotspot or Mi-Fi device, an Internet of Things (IoT) device, a watch or other wearable, a head-mounted display (HMD), a vehicle, a drone, a medical device and applications (e.g., remote surgery), an industrial device and applications (e.g., a robot and/or other wireless devices operating in an industrial and/or an automated processing chain contexts), a consumer electronics device, a device operating on commercial and/or industrial wireless networks, and the like. Any of the WTRUs 102a, 102b, 102c and 102d may be interchangeably referred to as a UE.

The communications systems 100 may also include a base station 114a and/or a base station 114b. Each of the base stations 114a, 114b may be any type of device configured to wirelessly interface with at least one of the WTRUs 102a, 102b, 102c, 102d to facilitate access to one or more communication networks, such as the CN 106, the Internet 110, and/or the other networks 112. By way of example, the base stations 114a, 114b may be a base transceiver station (BTS), a NodeB, an eNode B (eNB), a Home Node B, a Home eNode B, a next generation NodeB, such as a gNode B (gNB), a new radio (NR) NodeB, a site controller, an access point (AP), a wireless router, and the like. While the base stations 114a, 114b are each depicted as a single element, it will be appreciated that the base stations 114a, 114b may include any number of interconnected base stations and/or network elements.

The base station 114a may be part of the RAN 104, which may also include other base stations and/or network elements (not shown), such as a base station controller (BSC), a radio network controller (RNC), relay nodes, and the like. The base station 114a and/or the base station 114b may be configured to transmit and/or receive wireless signals on one or more carrier frequencies, which may be referred to as a cell (not shown). These frequencies may be in licensed spectrum, unlicensed spectrum, or a combination of licensed and unlicensed spectrum. A cell may provide coverage for a wireless service to a specific geographical area that may be relatively fixed or that may change over time. The cell may further be divided into cell sectors. For example, the cell associated with the base station 114a may be divided into three sectors. Thus, in one embodiment, the base station 114a may include three transceivers, i.e., one for each sector of the cell. In an embodiment, the base station 114a may employ multiple-input multiple output (MIMO) technology and may utilize multiple transceivers for each sector of the cell. For example, beamforming may be used to transmit and/or receive signals in desired spatial directions.

The base stations 114a, 114b may communicate with one or more of the WTRUs 102a, 102b, 102c, 102d over an air interface 116, which may be any suitable wireless communication link (e.g., radio frequency (RF), microwave, centimeter wave, micrometer wave, infrared (IR), ultraviolet (UV), visible light, etc.). The air interface 116 may be established using any suitable radio access technology (RAT).

More specifically, as noted above, the communications system 100 may be a multiple access system and may employ one or more channel access schemes, such as CDMA, TDMA, FDMA, OFDMA, SC-FDMA, and the like. For example, the base station 114a in the RAN 104 and the WTRUs 102a, 102b, 102c may implement a radio technology such as Universal Mobile Telecommunications System (UMTS) Terrestrial Radio Access (UTRA), which may establish the air interface 116 using wideband CDMA (WCDMA). WCDMA may include communication protocols such as High-Speed Packet Access (HSPA) and/or Evolved HSPA (HSPA+). HSPA may include High-Speed Downlink (DL) Packet Access (HSDPA) and/or High-Speed Uplink (UL) Packet Access (HSUPA).

In an embodiment, the base station 114a and the WTRUs 102a, 102b, 102c may implement a radio technology such as Evolved UMTS Terrestrial Radio Access (E-UTRA), which may establish the air interface 116 using Long Term Evolution (LTE) and/or LTE-Advanced (LTE-A) and/or LTE-Advanced Pro (LTE-A Pro).

In an embodiment, the base station 114a and the WTRUs 102a, 102b, 102c may implement a radio technology such as NR Radio Access, which may establish the air interface 116 using NR.

In an embodiment, the base station 114a and the WTRUs 102a, 102b, 102c may implement multiple radio access technologies. For example, the base station 114a and the WTRUs 102a, 102b, 102c may implement LTE radio access and NR radio access together, for instance using dual connectivity (DC) principles. Thus, the air interface utilized by WTRUs 102a, 102b, 102c may be characterized by multiple types of radio access technologies and/or transmissions sent to/from multiple types of base stations (e.g., an eNB and a gNB).

In other embodiments, the base station 114a and the WTRUs 102a, 102b, 102c may implement radio technologies such as IEEE 802.11 (i.e., Wireless Fidelity (WiFi), IEEE 802.16 (i.e., Worldwide Interoperability for Microwave Access (WiMAX)), CDMA2000, CDMA2000 1×, CDMA2000 EV-DO, Interim Standard 2000 (IS-2000), Interim Standard 95 (IS-95), Interim Standard 856 (IS-856), Global System for Mobile communications (GSM), Enhanced Data rates for GSM Evolution (EDGE), GSM EDGE (GERAN), and the like.

The base station 114b in FIG. 1A may be a wireless router, Home Node B, Home eNode B, or access point, for example, and may utilize any suitable RAT for facilitating wireless connectivity in a localized area, such as a place of business, a home, a vehicle, a campus, an industrial facility, an air corridor (e.g., for use by drones), a roadway, and the like. In one embodiment, the base station 114b and the WTRUs 102c, 102d may implement a radio technology such as IEEE 802.11 to establish a wireless local area network (WLAN). In an embodiment, the base station 114b and the WTRUs 102c, 102d may implement a radio technology such as IEEE 802.15 to establish a wireless personal area network (WPAN). In yet another embodiment, the base station 114b and the WTRUs 102c, 102d may utilize a cellular-based RAT (e.g., WCDMA, CDMA2000, GSM, LTE, LTE-A, LTE-A Pro, NR etc.) to establish a picocell or femtocell. As shown in FIG. 1A, the base station 114b may have a direct connection to the Internet 110. Thus, the base station 114b may not be required to access the Internet 110 via the CN 106.

The RAN 104 may be in communication with the CN 106, which may be any type of network configured to provide voice, data, applications, and/or voice over internet protocol (VoIP) services to one or more of the WTRUs 102a, 102b, 102c, 102d. The data may have varying quality of service (QoS) requirements, such as differing throughput requirements, latency requirements, error tolerance requirements, reliability requirements, data throughput requirements, mobility requirements, and the like. The CN 106 may provide call control, billing services, mobile location-based services, pre-paid calling, Internet connectivity, video distribution, etc., and/or perform high-level security functions, such as user authentication. Although not shown in FIG. 1A, it will be appreciated that the RAN 104 and/or the CN 106 may be in direct or indirect communication with other RANs that employ the same RAT as the RAN 104 or a different RAT. For example, in addition to being connected to the RAN 104, which may be utilizing a NR radio technology, the CN 106 may also be in communication with another RAN (not shown) employing a GSM, UMTS, CDMA 2000, WiMAX, E-UTRA, or WiFi radio technology.

The CN 106 may also serve as a gateway for the WTRUs 102a, 102b, 102c, 102d to access the PSTN 108, the Internet 110, and/or the other networks 112. The PSTN 108 may include circuit-switched telephone networks that provide plain old telephone service (POTS). The Internet 110 may include a global system of interconnected computer networks and devices that use common communication protocols, such as the transmission control protocol (TCP), user datagram protocol (UDP) and/or the internet protocol (IP) in the TCP/IP internet protocol suite. The networks 112 may include wired and/or wireless communications networks owned and/or operated by other service providers. For example, the networks 112 may include another CN connected to one or more RANs, which may employ the same RAT as the RAN 104 or a different RAT.

Some or all of the WTRUs 102a, 102b, 102c, 102d in the communications system 100 may include multi-mode capabilities (e.g., the WTRUs 102a, 102b, 102c, 102d may include multiple transceivers for communicating with different wireless networks over different wireless links). For example, the WTRU 102c shown in FIG. 1A may be configured to communicate with the base station 114a, which may employ a cellular-based radio technology, and with the base station 114b, which may employ an IEEE 802 radio technology.

FIG. 1B is a system diagram illustrating an example WTRU 102. As shown in FIG. 1B, the WTRU 102 may include a processor 118, a transceiver 120, a transmit/receive element 122, a speaker/microphone 124, a keypad 126, a display/touchpad 128, non-removable memory 130, removable memory 132, a power source 134, a global positioning system (GPS) chipset 136, and/or other peripherals 138, among others. It will be appreciated that the WTRU 102 may include any sub-combination of the foregoing elements while remaining consistent with an embodiment.

The processor 118 may be a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs), any other type of integrated circuit (IC), a state machine, and the like. The processor 118 may perform signal coding, data processing, power control, input/output processing, and/or any other functionality that enables the WTRU 102 to operate in a wireless environment. The processor 118 may be coupled to the transceiver 120, which may be coupled to the transmit/receive element 122. While FIG. 1B depicts the processor 118 and the transceiver 120 as separate components, it will be appreciated that the processor 118 and the transceiver 120 may be integrated together in an electronic package or chip.

The transmit/receive element 122 may be configured to transmit signals to, or receive signals from, a base station (e.g., the base station 114a) over the air interface 116. For example, in one embodiment, the transmit/receive element 122 may be an antenna configured to transmit and/or receive RF signals. In an embodiment, the transmit/receive element 122 may be an emitter/detector configured to transmit and/or receive IR, UV, or visible light signals, for example. In yet another embodiment, the transmit/receive element 122 may be configured to transmit and/or receive both RF and light signals. It will be appreciated that the transmit/receive element 122 may be configured to transmit and/or receive any combination of wireless signals.

Although the transmit/receive element 122 is depicted in FIG. 1B as a single element, the WTRU 102 may include any number of transmit/receive elements 122. More specifically, the WTRU 102 may employ MIMO technology. Thus, in one embodiment, the WTRU 102 may include two or more transmit/receive elements 122 (e.g., multiple antennas) for transmitting and receiving wireless signals over the air interface 116.

The transceiver 120 may be configured to modulate the signals that are to be transmitted by the transmit/receive element 122 and to demodulate the signals that are received by the transmit/receive element 122. As noted above, the WTRU 102 may have multi-mode capabilities. Thus, the transceiver 120 may include multiple transceivers for enabling the WTRU 102 to communicate via multiple RATs, such as NR and IEEE 802.11, for example.

The processor 118 of the WTRU 102 may be coupled to, and may receive user input data from, the speaker/microphone 124, the keypad 126, and/or the display/touchpad 128 (e.g., a liquid crystal display (LCD) display unit or organic light-emitting diode (OLED) display unit). The processor 118 may also output user data to the speaker/microphone 124, the keypad 126, and/or the display/touchpad 128. In addition, the processor 118 may access information from, and store data in, any type of suitable memory, such as the non-removable memory 130 and/or the removable memory 132. The non-removable memory 130 may include random-access memory (RAM), read-only memory (ROM), a hard disk, or any other type of memory storage device. The removable memory 132 may include a subscriber identity module (SIM) card, a memory stick, a secure digital (SD) memory card, and the like. In other embodiments, the processor 118 may access information from, and store data in, memory that is not physically located on the WTRU 102, such as on a server or a home computer (not shown).

The processor 118 may receive power from the power source 134, and may be configured to distribute and/or control the power to the other components in the WTRU 102. The power source 134 may be any suitable device for powering the WTRU 102. For example, the power source 134 may include one or more dry cell batteries (e.g., nickel-cadmium (NiCd), nickel-zinc (NiZn), nickel metal hydride (NiMH), lithium-ion (Li-ion), etc.), solar cells, fuel cells, and the like.

The processor 118 may also be coupled to the GPS chipset 136, which may be configured to provide location information (e.g., longitude and latitude) regarding the current location of the WTRU 102. In addition to, or in lieu of, the information from the GPS chipset 136, the WTRU 102 may receive location information over the air interface 116 from a base station (e.g., base stations 114a, 114b) and/or determine its location based on the timing of the signals being received from two or more nearby base stations. It will be appreciated that the WTRU 102 may acquire location information by way of any suitable location-determination method while remaining consistent with an embodiment.

The processor 118 may further be coupled to other peripherals 138, which may include one or more software and/or hardware modules that provide additional features, functionality and/or wired or wireless connectivity. For example, the peripherals 138 may include an accelerometer, an e-compass, a satellite transceiver, a digital camera (for photographs and/or video), a universal serial bus (USB) port, a vibration device, a television transceiver, a hands free headset, a Bluetooth® module, a frequency modulated (FM) radio unit, a digital music player, a media player, a video game player module, an Internet browser, a Virtual Reality and/or Augmented Reality (VR/AR) device, an activity tracker, and the like. The peripherals 138 may include one or more sensors. The sensors may be one or more of a gyroscope, an accelerometer, a hall effect sensor, a magnetometer, an orientation sensor, a proximity sensor, a temperature sensor, a time sensor; a geolocation sensor, an altimeter, a light sensor, a touch sensor, a magnetometer, a barometer, a gesture sensor, a biometric sensor, a humidity sensor and the like.

The WTRU 102 may include a full duplex radio for which transmission and reception of some or all of the signals (e.g., associated with particular subframes for both the UL (e.g., for transmission) and DL (e.g., for reception) may be concurrent and/or simultaneous. The full duplex radio may include an interference management unit to reduce and or substantially eliminate self-interference via either hardware (e.g., a choke) or signal processing via a processor (e.g., a separate processor (not shown) or via processor 118). In an embodiment, the WTRU 102 may include a half-duplex radio for which transmission and reception of some or all of the signals (e.g., associated with particular subframes for either the UL (e.g., for transmission) or the DL (e.g., for reception).

FIG. 1C is a system diagram illustrating the RAN 104 and the CN 106 according to an embodiment. As noted above, the RAN 104 may employ an E-UTRA radio technology to communicate with the WTRUs 102a, 102b, 102c over the air interface 116. The RAN 104 may also be in communication with the CN 106.

The RAN 104 may include eNode-Bs 160a, 160b, 160c, though it will be appreciated that the RAN 104 may include any number of eNode-Bs while remaining consistent with an embodiment. The eNode-Bs 160a, 160b, 160c may each include one or more transceivers for communicating with the WTRUs 102a, 102b, 102c over the air interface 116. In one embodiment, the eNode-Bs 160a, 160b, 160c may implement MIMO technology. Thus, the eNode-B 160a, for example, may use multiple antennas to transmit wireless signals to, and/or receive wireless signals from, the WTRU 102a.

Each of the eNode-Bs 160a, 160b, 160c may be associated with a particular cell (not shown) and may be configured to handle radio resource management decisions, handover decisions, scheduling of users in the UL and/or DL, and the like. As shown in FIG. 1C, the eNode-Bs 160a, 160b, 160c may communicate with one another over an X2 interface.

The CN 106 shown in FIG. 1C may include a mobility management entity (MME) 162, a serving gateway (SGW) 164, and a packet data network (PDN) gateway (PGW) 166. While the foregoing elements are depicted as part of the CN 106, it will be appreciated that any of these elements may be owned and/or operated by an entity other than the CN operator.

The MME 162 may be connected to each of the eNode-Bs 162a, 162b, 162c in the RAN 104 via an S1 interface and may serve as a control node. For example, the MME 162 may be responsible for authenticating users of the WTRUs 102a, 102b, 102c, bearer activation/deactivation, selecting a particular serving gateway during an initial attach of the WTRUs 102a, 102b, 102c, and the like. The MME 162 may provide a control plane function for switching between the RAN 104 and other RANs (not shown) that employ other radio technologies, such as GSM and/or WCDMA.

The SGW 164 may be connected to each of the eNode Bs 160a, 160b, 160c in the RAN 104 via the S1 interface. The SGW 164 may generally route and forward user data packets to/from the WTRUs 102a, 102b, 102c. The SGW 164 may perform other functions, such as anchoring user planes during inter-eNode B handovers, triggering paging when DL data is available for the WTRUs 102a, 102b, 102c, managing and storing contexts of the WTRUs 102a, 102b, 102c, and the like.

The SGW 164 may be connected to the PGW 166, which may provide the WTRUs 102a, 102b, 102c with access to packet-switched networks, such as the Internet 110, to facilitate communications between the WTRUs 102a, 102b, 102c and IP-enabled devices.

The CN 106 may facilitate communications with other networks. For example, the CN 106 may provide the WTRUs 102a, 102b, 102c with access to circuit-switched networks, such as the PSTN 108, to facilitate communications between the WTRUs 102a, 102b, 102c and traditional land-line communications devices. For example, the CN 106 may include, or may communicate with, an IP gateway (e.g., an IP multimedia subsystem (IMS) server) that serves as an interface between the CN 106 and the PSTN 108. In addition, the CN 106 may provide the WTRUs 102a, 102b, 102c with access to the other networks 112, which may include other wired and/or wireless networks that are owned and/or operated by other service providers.

Although the WTRU is described in FIGS. 1A-1D as a wireless terminal, it is contemplated that in certain representative embodiments that such a terminal may use (e.g., temporarily or permanently) wired communication interfaces with the communication network.

In representative embodiments, the other network 112 may be a WLAN.

A WLAN in Infrastructure Basic Service Set (BSS) mode may have an Access Point (AP) for the BSS and one or more stations (STAs) associated with the AP. The AP may have access or an interface to a Distribution System (DS) or another type of wired/wireless network that carries traffic in to and/or out of the BSS. Traffic to STAs that originates from outside the BSS may arrive through the AP and may be delivered to the STAs. Traffic originating from STAs to destinations outside the BSS may be sent to the AP to be delivered to respective destinations. Traffic between STAs within the BSS may be sent through the AP, for example, where the source STA may send traffic to the AP and the AP may deliver the traffic to the destination STA. The traffic between STAs within a BSS may be considered and/or referred to as peer-to-peer traffic. The peer-to-peer traffic may be sent between (e.g., directly between) the source and destination STAs with a direct link setup (DLS). In certain representative embodiments, the DLS may use an 802.11e DLS or an 802.11z tunneled DLS (TDLS). A WLAN using an Independent BSS (IBSS) mode may not have an AP, and the STAs (e.g., all of the STAs) within or using the IBSS may communicate directly with each other. The IBSS mode of communication may sometimes be referred to herein as an “ad-hoc” mode of communication.

When using the 802.11ac infrastructure mode of operation or a similar mode of operations, the AP may transmit a beacon on a fixed channel, such as a primary channel. The primary channel may be a fixed width (e.g., 20 MHz wide bandwidth) or a dynamically set width. The primary channel may be the operating channel of the BSS and may be used by the STAs to establish a connection with the AP. In certain representative embodiments, Carrier Sense Multiple Access with Collision Avoidance (CSMA/CA) may be implemented, for example in 802.11 systems. For CSMA/CA, the STAs (e.g., every STA), including the AP, may sense the primary channel. If the primary channel is sensed/detected and/or determined to be busy by a particular STA, the particular STA may back off. One STA (e.g., only one station) may transmit at any given time in a given BSS.

High Throughput (HT) STAs may use a 40 MHz wide channel for communication, for example, via a combination of the primary 20 MHz channel with an adjacent or nonadjacent 20 MHz channel to form a 40 MHz wide channel.

Very High Throughput (VHT) STAs may support 20 MHz, 40 MHz, 80 MHz, and/or 160 MHz wide channels. The 40 MHz, and/or 80 MHz, channels may be formed by combining contiguous 20 MHz channels. A 160 MHz channel may be formed by combining 8 contiguous 20 MHz channels, or by combining two non-contiguous 80 MHz channels, which may be referred to as an 80+80 configuration. For the 80+80 configuration, the data, after channel encoding, may be passed through a segment parser that may divide the data into two streams. Inverse Fast Fourier Transform (IFFT) processing, and time domain processing, may be done on each stream separately. The streams may be mapped on to the two 80 MHz channels, and the data may be transmitted by a transmitting STA. At the receiver of the receiving STA, the above described operation for the 80+80 configuration may be reversed, and the combined data may be sent to the Medium Access Control (MAC).

Sub 1 GHz modes of operation are supported by 802.11af and 802.11ah. The channel operating bandwidths, and carriers, are reduced in 802.11af and 802.11ah relative to those used in 802.11n, and 802.11ac. 802.11af supports 5 MHz, 10 MHz, and 20 MHz bandwidths in the TV White Space (TVWS) spectrum, and 802.11ah supports 1 MHz, 2 MHz, 4 MHz, 8 MHz, and 16 MHz bandwidths using non-TVWS spectrum. According to a representative embodiment, 802.11ah may support Meter Type Control/Machine-Type Communications (MTC), such as MTC devices in a macro coverage area. MTC devices may have certain capabilities, for example, limited capabilities including support for (e.g., only support for) certain and/or limited bandwidths. The MTC devices may include a battery with a battery life above a threshold (e.g., to maintain a very long battery life).

WLAN systems, which may support multiple channels, and channel bandwidths, such as 802.11n, 802.11ac, 802.11af, and 802.11ah, include a channel which may be designated as the primary channel. The primary channel may have a bandwidth equal to the largest common operating bandwidth supported by all STAs in the BSS. The bandwidth of the primary channel may be set and/or limited by a STA, from among all STAs in operating in a BSS, which supports the smallest bandwidth operating mode. In the example of 802.11ah, the primary channel may be 1 MHz wide for STAs (e.g., MTC type devices) that support (e.g., only support) a 1 MHz mode, even if the AP, and other STAs in the BSS support 2 MHz, 4 MHz, 8 MHz, 16 MHz, and/or other channel bandwidth operating modes. Carrier sensing and/or Network Allocation Vector (NAV) settings may depend on the status of the primary channel. If the primary channel is busy, for example, due to a STA (which supports only a 1 MHz operating mode) transmitting to the AP, all available frequency bands may be considered busy even though a majority of the available frequency bands remains idle.

In the United States, the available frequency bands, which may be used by 802.11ah, are from 902 MHz to 928 MHz. In Korea, the available frequency bands are from 917.5 MHz to 923.5 MHz. In Japan, the available frequency bands are from 916.5 MHz to 927.5 MHz. The total bandwidth available for 802.11ah is 6 MHz to 26 MHz depending on the country code.

FIG. 1D is a system diagram illustrating the RAN 104 and the CN 106 according to an embodiment. As noted above, the RAN 104 may employ an NR radio technology to communicate with the WTRUs 102a, 102b, 102c over the air interface 116. The RAN 104 may also be in communication with the CN 106.

The RAN 104 may include gNBs 180a, 180b, 180c, though it will be appreciated that the RAN 104 may include any number of gNBs while remaining consistent with an embodiment. The gNBs 180a, 180b, 180c may each include one or more transceivers for communicating with the WTRUs 102a, 102b, 102c over the air interface 116. In one embodiment, the gNBs 180a, 180b, 180c may implement MIMO technology. For example, gNBs 180a, 108b may utilize beamforming to transmit signals to and/or receive signals from the gNBs 180a, 180b, 180c. Thus, the gNB 180a, for example, may use multiple antennas to transmit wireless signals to, and/or receive wireless signals from, the WTRU 102a. In an embodiment, the gNBs 180a, 180b, 180c may implement carrier aggregation technology. For example, the gNB 180a may transmit multiple component carriers to the WTRU 102a (not shown). A subset of these component carriers may be on unlicensed spectrum while the remaining component carriers may be on licensed spectrum. In an embodiment, the gNBs 180a, 180b, 180c may implement Coordinated Multi-Point (COMP) technology. For example, WTRU 102a may receive coordinated transmissions from gNB 180a and gNB 180b (and/or gNB 180c).

The WTRUs 102a, 102b, 102c may communicate with gNBs 180a, 180b, 180c using transmissions associated with a scalable numerology. For example, the OFDM symbol spacing and/or OFDM subcarrier spacing may vary for different transmissions, different cells, and/or different portions of the wireless transmission spectrum. The WTRUs 102a, 102b, 102c may communicate with gNBs 180a, 180b, 180c using subframe or transmission time intervals (TTIs) of various or scalable lengths (e.g., containing a varying number of OFDM symbols and/or lasting varying lengths of absolute time).

The gNBs 180a, 180b, 180c may be configured to communicate with the WTRUs 102a, 102b, 102c in a standalone configuration and/or a non-standalone configuration. In the standalone configuration, WTRUs 102a, 102b, 102c may communicate with gNBs 180a, 180b, 180c without also accessing other RANs (e.g., such as eNode-Bs 160a, 160b, 160c). In the standalone configuration, WTRUs 102a, 102b, 102c may utilize one or more of gNBs 180a, 180b, 180c as a mobility anchor point. In the standalone configuration, WTRUs 102a, 102b, 102c may communicate with gNBs 180a, 180b, 180c using signals in an unlicensed band. In a non-standalone configuration WTRUs 102a, 102b, 102c may communicate with/connect to gNBs 180a, 180b, 180c while also communicating with/connecting to another RAN such as eNode-Bs 160a, 160b, 160c. For example, WTRUs 102a, 102b, 102c may implement DC principles to communicate with one or more gNBs 180a, 180b, 180c and one or more eNode-Bs 160a, 160b, 160c substantially simultaneously. In the non-standalone configuration, eNode-Bs 160a, 160b, 160c may serve as a mobility anchor for WTRUs 102a, 102b, 102c and gNBs 180a, 180b, 180c may provide additional coverage and/or throughput for servicing WTRUs 102a, 102b, 102c.

Each of the gNBs 180a, 180b, 180c may be associated with a particular cell (not shown) and may be configured to handle radio resource management decisions, handover decisions, scheduling of users in the UL and/or DL, support of network slicing, DC, interworking between NR and E-UTRA, routing of user plane data towards User Plane Function (UPF) 184a, 184b, routing of control plane information towards Access and Mobility Management Function (AMF) 182a, 182b and the like. As shown in FIG. 1D, the gNBs 180a, 180b, 180c may communicate with one another over an Xn interface.

The CN 106 shown in FIG. 1D may include at least one AMF 182a, 182b, at least one UPF 184a, 184b, at least one Session Management Function (SMF) 183a, 183b, and possibly a Data Network (DN) 185a, 185b. While the foregoing elements are depicted as part of the CN 106, it will be appreciated that any of these elements may be owned and/or operated by an entity other than the CN operator.

The AMF 182a, 182b may be connected to one or more of the gNBs 180a, 180b, 180c in the RAN 104 via an N2 interface and may serve as a control node. For example, the AMF 182a, 182b may be responsible for authenticating users of the WTRUs 102a, 102b, 102c, support for network slicing (e.g., handling of different protocol data unit (PDU) sessions with different requirements), selecting a particular SMF 183a, 183b, management of the registration area, termination of non-access stratum (NAS) signaling, mobility management, and the like. Network slicing may be used by the AMF 182a, 182b in order to customize CN support for WTRUs 102a, 102b, 102c based on the types of services being utilized WTRUs 102a, 102b, 102c. For example, different network slices may be established for different use cases such as services relying on ultra-reliable low latency (URLLC) access, services relying on enhanced massive mobile broadband (eMBB) access, services for MTC access, and the like. The AMF 182a, 182b may provide a control plane function for switching between the RAN 104 and other RANs (not shown) that employ other radio technologies, such as LTE, LTE-A, LTE-A Pro, and/or non-3GPP access technologies such as WiFi.

The SMF 183a, 183b may be connected to an AMF 182a, 182b in the CN 106 via an N11 interface. The SMF 183a, 183b may also be connected to a UPF 184a, 184b in the CN 106 via an N4 interface. The SMF 183a, 183b may select and control the UPF 184a, 184b and configure the routing of traffic through the UPF 184a, 184b. The SMF 183a, 183b may perform other functions, such as managing and allocating UE IP address, managing PDU sessions, controlling policy enforcement and QoS, providing DL data notifications, and the like. A PDU session type may be IP-based, non-IP based, Ethernet-based, and the like.

The UPF 184a, 184b may be connected to one or more of the gNBs 180a, 180b, 180c in the RAN 104 via an N3 interface, which may provide the WTRUs 102a, 102b, 102c with access to packet-switched networks, such as the Internet 110, to facilitate communications between the WTRUs 102a, 102b, 102c and IP-enabled devices. The UPF 184a, 184b may perform other functions, such as routing and forwarding packets, enforcing user plane policies, supporting multi-homed PDU sessions, handling user plane QoS, buffering DL packets, providing mobility anchoring, and the like.

The CN 106 may facilitate communications with other networks. For example, the CN 106 may include, or may communicate with, an IP gateway (e.g., an IP multimedia subsystem (IMS) server) that serves as an interface between the CN 106 and the PSTN 108. In addition, the CN 106 may provide the WTRUs 102a, 102b, 102c with access to the other networks 112, which may include other wired and/or wireless networks that are owned and/or operated by other service providers. In one embodiment, the WTRUs 102a, 102b, 102c may be connected to a local DN 185a, 185b through the UPF 184a, 184b via the N3 interface to the UPF 184a, 184b and an N6 interface between the UPF 184a, 184b and the DN 185a, 185b.

In view of FIGS. 1A-1D, and the corresponding description of FIGS. 1A-1D, one or more, or all, of the functions described herein with regard to one or more of: WTRU 102a-d, Base Station 114a-b, eNode-B 160a-c, MME 162, SGW 164, PGW 166, gNB 180a-c, AMF 182a-b, UPF 184a-b, SMF 183a-b, DN 185a-b, and/or any other device(s) described herein, may be performed by one or more emulation devices (not shown). The emulation devices may be one or more devices configured to emulate one or more, or all, of the functions described herein. For example, the emulation devices may be used to test other devices and/or to simulate network and/or WTRU functions.

The emulation devices may be designed to implement one or more tests of other devices in a lab environment and/or in an operator network environment. For example, the one or more emulation devices may perform the one or more, or all, functions while being fully or partially implemented and/or deployed as part of a wired and/or wireless communication network in order to test other devices within the communication network. The one or more emulation devices may perform the one or more, or all, functions while being temporarily implemented/deployed as part of a wired and/or wireless communication network. The emulation device may be directly coupled to another device for purposes of testing and/or performing testing using over-the-air wireless communications.

The one or more emulation devices may perform the one or more, including all, functions while not being implemented/deployed as part of a wired and/or wireless communication network. For example, the emulation devices may be utilized in a testing scenario in a testing laboratory and/or a non-deployed (e.g., testing) wired and/or wireless communication network in order to implement testing of one or more components. The one or more emulation devices may be test equipment. Direct RF coupling and/or wireless communications via RF circuitry (e.g., which may include one or more antennas) may be used by the emulation devices to transmit and/or receive data.

The spectrum of a line encoded signal may be shifted in frequency. This may be used for example to multiplex multiple device-to-reader (D2R) transmissions within the same channel wherein each of the multiplexed D2R transmissions may occupy different spectral resources in the channel.

There may be various methods to implement frequency shift. In a first method, a subcarrier signal (that is usually a square wave) is used to multiply the line coded signal. The multiplication may be achieved by an exclusive or (XOR) operation (if voltage levels are unipolar) or scalar multiplication (if voltage levels are polar). The resulting signal may then be transmitted using backscatter modulation.

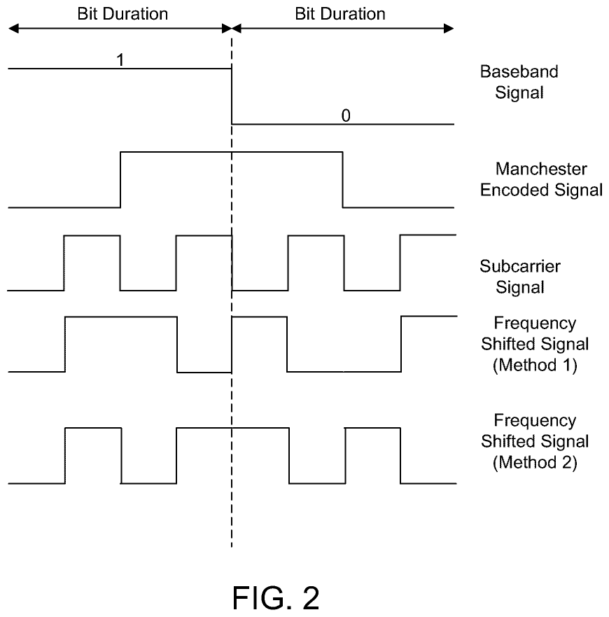

FIG. 2 is a transmission diagram illustrating examples of frequency shift methods. As shown in FIG. 2, two baseband bits are encoded using Manchester encoding. The Manchester codewords are multiplied with a carrier signal to generate a signal whose spectrum is shifted in frequency wherein the shift depends on the frequency of the subcarrier modulation signal. The frequency of the subcarrier modulation signal is determined as the number of square wave periods/cycles within one Manchester codeword duration (i.e., data bit) duration. For example, in FIG. 2, there are two periods of the square wave within one codeword. The number of periods within one Manchester codeword duration may be referred to as M. Multiple devices may be multiplexed in the same channel if the devices use subcarriers signal with different frequencies (e.g., M=2, 4, 8).

A second alternative method to implement frequency shift is to repeat the Manchester codeword M times within one bit duration. This method may be equivalent to multiplying the baseband bits with a subcarrier signal.

Examples of random access in AIoT are provided herein. A random access procedure based on the following three steps may be performed for AIoT after a device determines its transmission occasion.

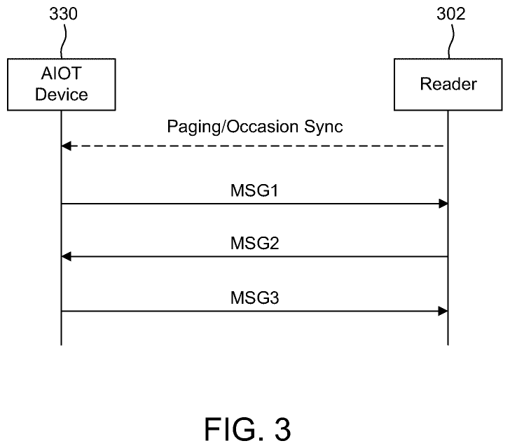

FIG. 3 is a signaling diagram illustrating an example of a random access procedure for an AIoT device. As shown in FIG. 3, a reader device 302 may transmit a paging or occasion synchronization message to an AIoT device 330. In an example, the reader device 302 may be a WTRU reader device and may be the same as, or similar to, the WTRU 102.

Further, the AIoT device 330 may transmit a MSG1 to the reader 302. The MSG1 may contain a random identity (ID). In response, the reader 302 may transmit a MSG2 back to the AIoT device 330. The MSG2 may include, or may echo, the random ID.

Moreover, the AIoT device 330 may transmit a MSG3 to the reader 302. The MSG3 may include the device ID of the AIoT device 330, application layer data, or both.

The reader 302 (which may be referred to as an interrogator), may be a gNB, a base station, a WTRU, or another wireless device. The methods described herein may not be limited to IoT devices performing backscattering. They may also be applicable to IoT devices that can generate an RF carrier (that does not need an external carrier), and other wireless devices.

The reader may use On-Off Keying (OOK) modulated signal to transmit a baseband signal to a device. The baseband signal may be a line encoded signal. For 3GPP Ambient IoT, it has been agreed that an OFDM-based OOK waveform with subcarrier spacing of 15 kHz may be used, as studied, for Reader-to-Device (R2D) transmission as shown in recent standards technical reports. Device-to-Reader transmission may be referred to as D2R transmission.

Radio frequency identification (RFID) is usually used currently for applications of asset identification. The high-level summary of the inventory procedure from RFID is shown below.

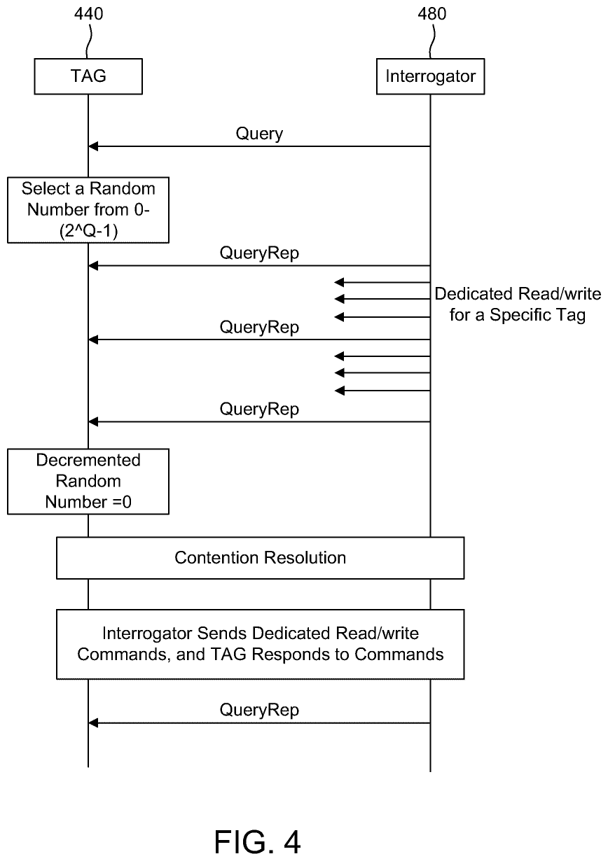

FIG. 4 is a signaling diagram illustrating an example of an RFID inventory procedure. In the inventory procedure, an interrogator (reader) 480 sends a Query message to energize all or a subset of TAGs, such as TAG 440. Following a Query message, the TAG 440 selects a random number from 0-2\hat{ }Q-1 and loads its memory with that number. At each transmission of a QueryRep, the TAG 440 decrements its counter until the counter reaches 0. When the counter reaches 0, the TAG 440 initiates a contention resolution procedure which consists of transmitting its device ID in the uplink and waiting for confirmation of the device ID in the downlink (to address possible collision between multiple devices selecting the same random number). For a device that has passed contention resolution, the interrogator 480 can send multiple read/write commands, to which the TAG 440 should respond.

For AIoT, 3GPP supports FDMA using small frequency shift in the Device-to-Reader Channel (multiple devices can transmit on different frequency resources to the same reader). A device first encodes the data bits using a convolutional encoder. Then, the channel coded bits are encoded using Manchester encoding. To support FDMA, the spectrum of the Manchester codeword may be shifted in frequency. Multiple devices shift their signals to different frequencies.

Two example current methods to perform frequency shift using Manchester encoding are provided in the following. In a first example method, a Manchester codeword is multiplied (e.g., using XOR) within one bit duration with a square wave clock signal. The resultant signal is transmitted.

In a second example method, a Manchester codeword is repeated M times within one bit duration. This method is equivalent to transmitting a square wave clock signal within one bit duration with a period corresponding to the desired frequency shift. To transmit bit 0 or 1, the phase of the clock signal is changed.

One problem with these current methods is that, given a bit duration, the locations of the frequency shifts are limited. Specifically, the frequency shift is determined by the chip duration of the square wave clock signal (Fs=1/(2Tc)) but since the number of chips within a bit duration is an integer, not all frequencies can be indicated.

Another problem is how to signal efficiently the frequency resources to multiple devices. One final issue is how to support both methods and if a method is selected by the device, how does the reader know the selected method.

Embodiments and examples are provided herein to coordinate frequency shifts between and among wireless devices, such as AIoT devices. In an example, a reader transmits an R2D message (such as a paging message, for example) containing at least a resource allocation configuration wherein the resource allocation contains one or more of the following. The resource allocation may contain one or more scaling factors. Further, the resource allocation may contain a set of number of square wave clock cycles associated with a scaling factor. For example, the set may be {α1: M2, M4, M8; α2: M8} wherein α1 and α2 are scaling factors and M2, M4, M8 are square wave clock cycles. In an example, the number of times a device is expected to transmit or repeat a Manchester codeword in one bit duration is determined based on the number of clock cycle durations in a bit duration. In another example, the bit duration is determined by the device from a measured R2D transmission duration scaled by an indicated scaling factor.

Further, the reader transmits a preamble using a chip duration determined by the R2D data rate. The preamble may be an R2D preamble. In a further example, the reader may transmit, in an associated control message, at least one scaling factor.

Also, the reader monitors for reception of one or a plurality of D2R preambles. Additionally, the reader determines, based on a received D2R preamble one or more of: a device-selected square wave clock cycle (from the configured set of number of square wave cycles associated with the indicated scaling factor), and a device-selected type of small frequency shift. In an example, the device-selected square wave clock cycles is determined from the chip duration of the received R2D preamble and the indicated scaling factor.

Moreover, the device monitors one or a plurality of D2R transmissions with D2R transmission parameters determined based on one or more of the determined device-selected square wave clock cycles and type of small frequency shift of the received D2R preamble.

In embodiments and examples provided herein, the terms device, IoT device, and tag may be used interchangeably to mean the IoT device that is being inventoried/queried by the reader. The term reader refers to the entity which queries the AIoT device. The term reader may refer to a network node or a WTRU, depending on the context and/or the topology. The methods disclosed here as applicable to IoT devices may also be used by other wireless devices such as WTRUs.

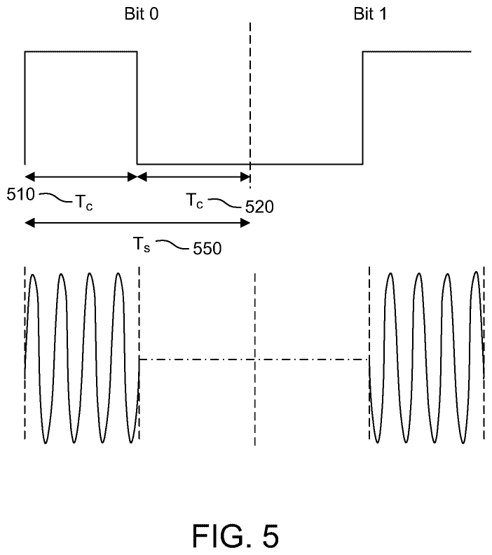

FIG. 5 is a transmission diagram illustrating an example of backscattering modulation. FIG. 5 shows the concept of backscatter modulation and some related terminology. Using a line encoding scheme, bit 0 is encoded as a pulse of amplitude 1 followed by a pulse of amplitude 0; and bit 1 is encoded as a pulse of amplitude 0 followed by a pulse of amplitude 1 (as previously mentioned line code is known as Manchester encoding). The bit (or symbol) duration is denoted as Ts 550. A chip may be defined as the smallest unit of pulse and the amplitude of a chip is assumed to be constant over the chip duration Tc 510. A symbol may comprise of one or more chips, for example in this figure, each Manchester symbol is composed of two chips. For example, Bit 0 is encoded across two chip durations Tc 510, 520.

The baseband line code modulates a received RF sinusoidal carrier. In this example, the amplitude of the backscattered signal is changed depending on the value of the line code chip. For example, when a baseband chip has value 1, the received RF carrier is reflected as it is during the duration of Tc; when a baseband chip has value 0, the received RF carrier is absorbed by the device, and nothing is backscattered.

In embodiments and examples provided herein, the term inventory refers to the overall procedure of a reader triggering access by multiple devices using a sequence of messages (e.g., similar to query, followed by query rep in RFID). Specifically, the inventory procedure refers to a single round of attempts to have each device respond or attempt to respond with an access ID or perform a random access channel (RACH) procedure. Specifically, the inventory procedure refers to a set of access occasions which may have 0 or at least 1 device respond within the access occasion.

In embodiments and examples provided herein, the term occasion refers to the opportunity for device transmission that may be delimited by the transmission of a query rep message (or similar). Specifically, a device may perform transmission in an occasion by performing a AIOT transmission in a defined time following the query rep associated with that transmission. Additionally or alternatively, an occasion may consist of both a time aspect and a frequency aspect. Specifically, a device may determine an occasion as a transmission following a specific query rep, and by transmitting on one of a number of frequencies (e.g., FDM). Wherever solutions indicate selection of an occasion, they can apply equivalently to selection of only a time component and/or selection of a frequency component.

In embodiments and examples provided herein, depending on the solution or description, any reference to time can be associated with an absolute time measurement (e.g., seconds, slots, frames, etc.). Additionally or alternatively, it can refer to a number of executions of a procedure, possibly triggered by a reader (e.g., number of inventory procedures, number of accesses or RACH procedures, etc.). Additionally or alternatively, it can refer to a number of messages, possibly of a specific type, or containing specific information, as described herein, received or transmitted.

In embodiments and examples provided herein, configuration or pre-configuration may refer to any configuration received by a message (e.g., a radio resource control (RRC) message, a MAC control element (CE), a physical (PHY) layer signal, a data protocol data unit (PDU), a control PDU associated with any or a new protocol layer, etc.) received from either a network node, or from another device or WTRU.

A device herein may be configured by the reader, whereby the reader may be a network node or a WTRU. In the case of a WTRU, the WTRU may derive the device configuration itself, or receive the device configuration from the network, in which case, the device configuration is being relayed from the network to the device by the WTRU. On the other hand, a WTRU configuration may be received from a network node (e.g., the gNB).

In an example method of a solution, the reader may transmit a message wherein the message may contain control information. Control information may contain configuration of one or more R2D/D2R transmission parameters. The control information may be associated with a time frame wherein association may mean that the control information is valid and/or applicable within the associated time frame, and/or until the control information is updated/changed/cancelled. For example, the control information may be applicable for an inventory round. In another example, the control information may be applicable for transmission within a slot of an inventory round. The control information may be applicable to a transmission; for example, control information transmitted in msg2 may be applicable to D2R transmission in msg3.

Control information may be indicated in a plurality of messages. For example, a first set of parameters may be indicated in a first message and a subset of the first set of parameters may be indicated/activated/selected for by a second message. In one solution, the first message may be a message indicating parameters for an inventory round and the second message may be a message indicating parameters for transmission in a slot (or part of a slot) in an inventory round.

In an example method, the reader may indicate to the device one or more of the following. The reader may indicate the chip duration (or similarly the chip rate since chip rate may be defined as 1/(chip duration) the reader uses to transmit in the D2R channel. The chip duration may be the chip duration of a codeword (e.g., a Manchester codeword) or the chip duration of a signal computed after a codeword is subject to further processing (e.g., chip duration after repetition, chip duration after multiplying with a subcarrier signal). For example, if the chip duration of a Manchester codeword is Tc (bit duration is 2 Tc) and the codeword is repeated M times within the bit duration, the transmitted chip duration becomes Tc/M.

Additionally or alternatively, the reader may indicate the chip duration of a subcarrier signal used to multiply a codeword, or the number of cycles/periods (M) of the subcarrier signal within a bit duration (equivalent the number of repetitions M of the codeword within a bit duration). Additionally or alternatively, the reader may indicate the bit rate (data rate) and/or coding rate.

In embodiments and examples provided herein, a codeword chip may be described as the chip of a codeword while a chip may be a general parameter that may refer to any chip. A D2R chip may be a codeword chip or a chip of the signal transmitted wherein the final signal may be after a codeword is processed further. Unless otherwise noted, the methods described herein apply to both. If needed, the chip type is mentioned. As a general matter, a set of values for a parameter may be preconfigured/indicated/signaled, and the indication may be an index to one of values of the parameter.

In examples provided herein the reader indicates a codeword chip/bit duration. For example, a reader may use one or a combination of a plurality of the following methods to indicate to a device the D2R chip rate (similarly the D2R chip duration).

The reader may indicate to a device the number of samples in a D2R signal, e.g., a D2R chip, codeword chip or bit. In one example solution, a sampling rate may be determined, for example, may be fixed in a specification, and the reader may indicate the number of samples wherein the number of samples is determined using the determined sampling rate.

For example, if the sampling rate is 1.92 MHz (corresponding to one sample duration being approximately 1/1.92~=0.5 μs), and the reader indicates N samples for a D2R chip, then a chip duration may be approximately 0.5N μs. The device then is expected to generate and transmit chips of duration 0.5N μs. Note that the actual sample duration generated by the device may be different than 0.5 μs due to sampling frequency offset at the device.

In an example solution, a device with a different sampling rate than the specified value may scale the number of samples as to generate the signal with the indicated duration. For example, a device may have a sampling rate of twice the specified value, and this device may use 2N samples to generate a chip of duration 0.5N μs.

The reader may indicate an absolute value of a D2R signal duration given in seconds (e.g., μs). A device may determine a D2R chip duration from a measurement performed on a R2D signal. In one example solution, the device may measure an R2D signal duration (e.g., a R2D chip in a preamble, in a control message, in a data message) and may scale the measured value with a scaling factor. The device may determine the scaled value as the value of a D2R signal duration such as a D2R chip duration.

One or more of the following may be used to indicate a scaling factor. A set of scaling factors may be predetermined, for example, by specification. A first set of scaling factors may take values larger than 1 (including 1) and a second set of scaling factors may take values between 0 and 1 (including 1 if not included as part of the first set). In one example solution, all scaling factors may be listed, for example, in a table. In another example solution, scaling factors in the first may be listed in a first table and scaling factors in the second set (including 1 if not included as part of the first set) may be listed in a second table.

The reader may indicate one or a plurality of scaling factors using one or a combination of the following. The reader may indicate using a bitmap wherein the bitmap size may be same as the number of entries in a table. The reader may indicate a range, for example by sending two indices, one indicating a first factor and another indicating another factor and factors in between being determined by the device. The reader may indicate one entry from the table and device uses the corresponding factor. The reader may indicate one entry from the table, and the device may use the corresponding factors below (or above) that entry. The reader may indicate a table index, if more than one table.

To indicate a scaling factor, the reader may indicate one or a plurality of coefficients. A device may use one or a plurality of the coefficients as input to a function to determine one or more scaling factors. The following may apply. A reader may indicate an integer K and the device may determine a scaling factor as 2K. The reader may indicate an integer K and sign of the integer (positive or negative) and the device may determine a scaling factor as 2K or 2^{-K}. The reader may indicate an integer K and possibly the sign of the integer (positive or negative) and the device may determine scaling factors as β=2^{k} or β=2^{k}, where k=0, 1, 2, . . . . K (or K−1). Note that k=0 denotes scaling factor 1, i.e., no scaling, so may be omitted. Further, the reader may indicate an integer K and possibly the sign of the integer (positive or negative) and the device may determine scaling factors as β=1, 2, 3, . . . . K (or K−1); or β=1, ½, ⅓, . . . , 1/K (or 1/(K−1)). Also, the reader may indicate an integer K and the device may determine scaling factors as β=1, 2, 3, . . . 2K or β=1, ½, ⅓, . . . ½K. The reader may also indicate whether the scaling factor is greater or smaller than 1.

A possible set of scaling factors may be configured and/or indicated in a first message, using one or a combination of the methods above. For example, a first message may be paging message or a message used to carry control information that may be valid for a specific duration. For example, the information may be valid for the subsequent inventory A second message may be used to choose/select/indicate one of the values configured/indicated in the first message. For example, the second message may be a control message specifying transmission parameters that may be used in a slot of the inventory round. For example, the second message may be a random access trigger message such as a QueryRep (or a message having similar functionality), a msg2 scheduling msg3 transmission, etc. For example, the reader may configure a set of scaling factors before an inventory round starts, and may indicate one of the configured scaling factors wherein the indicated scaling factor may be valid/applicable (i.e. used by the corresponding devices) during a time interval within the inventory round.

The reader may indicate to a device the D2R data rate. From the data rate, device may determine the codeword chip/bit duration. Data rate may be indicated with coding rate and device would perform the computation accordingly.

In examples provided herein, the reader indicates a repetition factor M. A set of repetition factors (or similarly subcarrier cycles/periods within one bit duration, or M value) may be predetermined, for example, by specification. In one example solution, all possible repetition factors may be listed, for example, in a table.

The reader may indicate one or a plurality of repetition factors using one or a combination of the following. The reader may indicate a subset of the predetermined repetition factors using a bitmap. Further, the reader may indicate repetition factors within a range of the predetermined set. For example, the reader may send two indices wherein each index indicates one entry in the table, and the device may determine the repetition factors between (and maybe including) the entries of the table. Also, the reader may indicate one entry from the table. Additionally, the reader may indicate one entry from the table and the device may determine the repetition factors below (or above) that entry in the table (maybe including the indicated entry).

The reader may indicate one or a plurality of coefficients. A device may use one or a plurality of the coefficients as input to a function to determine one or more repetition factors. The following may apply. The reader may indicate an integer K and the device may determine a repetition factor as 2^{K}. Further, the reader may indicate an integer K and the device may determine repetition factors as M=1, 2, 3, . . . 2^{K}. Also, the reader may indicate an integer K and the device may determine repetition factors as M=2^{k} where k=1, 2, 3, . . . , K; or k=1, 2, 3, . . . , K−1. Note that k=0 (M=1) results in no repetition, i.e., codeword is transmitted without further processing (no frequency shift).

The reader may indicate a repetition factor using L bits per value and S values (using LS bits).

In an example solution, a reader may determine the largest repetition factor a device is expected to support from a device capability and/or another limitation. A device may be expected to support a repetition factor only if the smallest chip duration when the repetition factor is applied is not smaller than a value. For example, if the sampling rate at the device is 1.92 MHz, then a device may not be able to transmit (e.g., reliably) a chip of duration less than 4 samples (corresponding to approximately 2 μs). In another example, the smallest chip duration that a device can support may be determined from the highest data rate.

In an example method, a reader may determine that one or more of the indicated repetition factors may not be supported and/or used by any device. For example, the reader may indicate a parameter K (or K may be predetermined, e.g., by specification) and may determine possible repetition factors as M=2^{k}, k=1, 2, . . . . K where K is a parameter to define the maximum repetition factor. Continuing the same example, the reader may also determine that M=2ⁿ is the largest possible repetition factor that may be supported by a device because the chip duration (2×D2R codeword chip duration/2ₙ) results in the smallest chip duration a device may support. Therefore, the reader may determine to monitor frequencies that correspond to repetition factors 2, 3, . . . , 2ⁿ, and not monitor frequencies that correspond to repetition factors 2ⁿ⁺¹, 2ⁿ⁺², . . . 2^{K}.

Further, in an example solution, a reader may determine an association between a scaling factor (and/or a D2R codeword chip/bit duration) and the set of possible repetition factors that may be supported for that scaling factor. In one solution, a set of repetition factors may be configured and/or indicated in a first message. For example, a paging message or a message used to carry control information valid for a specific duration. For example, valid for the subsequent inventory. A second message may be used to choose/select/indicate one of the values configured/indicated in the first message. For example, the second message may be a control message specifying transmission parameters for a slot. For example, a RACH trigger message such as a QueryRep, msg2 scheduling msg transmission etc. For example, an index to the determined set.

In one example, the reader may indicate a plurality of repetition factors in a paging message (or another configuration message wherein the configured parameters may be valid during the duration of an inventory procedure and/or until the parameters are updated). A device may choose one of the indicated repetition factors randomly to use in msg1 transmission. During msg3 transmission, the device may continue using the same repetition factor, or the device may be assigned another repetition factor, for example the assignment may be indicated in msg2 by the reader. The reader in msg2 may indicate to a device one of the configured repetition factors (e.g., using ceil (log 2(n)) bits to indicate one of n configured repetition factors.

The bandwidth of the Manchester encoded signal depends on the Manchester codeword chip duration and may be approximated by 2/(Tc) Hz wherein Tc is the Manchester codeword chip duration and the bandwidth is defined as the spectrum containing the main lobes.

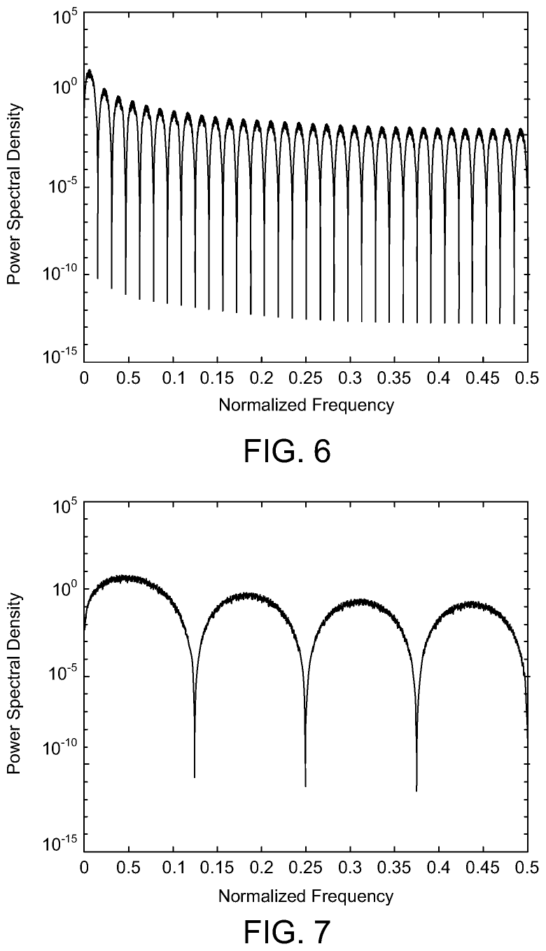

FIG. 6 is a transmission diagram illustrating an example of power spectral density of Manchester encoding with sixty-four (64) sample chips. Accordingly, FIG. 6 shows the bandwidth with Tc=64 samples.

FIG. 7 is a transmission diagram illustrating an example of power spectral density of Manchester encoding with eight (8) sample chips. Accordingly, FIG. 7 shows the bandwidth with Tc=8 samples.

As the bandwidth with longer chip duration is narrower, more devices may share the channel and since the bandwidth with shorter chip duration is wider fewer devices may share the channel. The shift applied to the spectrum may be approximated by (M/2Tc) Hz where M is the number of periods of the subcarrier signal (or the number of repetitions of the Manchester codeword within a bit duration).

The number of devices multiplexed in time may be determined by the Manchester codeword chip duration (equivalently data rate since one bit is encoded as one Manchester codeword). The number of repetition factors applicable within a Manchester codeword may be determined by the Manchester codeword chip duration.

In one example method, the reader may determine a D2R codeword chip/bit duration and a number of repetition factors (or equivalently a number of periods of a subcarrier signal within a bit duration, or a number of subbands/subchannels in a channel, a number of devices multiplexed) associated with the codeword chip/bit duration.

In one example method, the reader may determine a scaling factor and a number of repetition factors (or equivalently a number of periods of a subcarrier signal within a bit duration, or a number of subbands/subchannels in a channel, a number of devices multiplexed) associated with the codeword chip/bit duration.

In one example method, the reader may determine a D2R data rate (or link frequency) and a number of repetition factors (or equivalently a number of periods of a subcarrier signal within a bit duration, or a number of subbands/subchannels in a channel, a number of devices multiplexed) associated with the codeword chip/bit duration.

The reader may use one or a plurality of the following to determine the said association. The reader may use a configuration by the network. The network may configure the smallest chip duration (or equivalently the largest chip rate) a device can transmit. From the chip duration, a reader may determine the repetition factors. For example, if the D2R bit duration is determined as 64 samples (~32 μs) by the reader, and the smallest chip duration is 8 (~4 μs) samples (e.g., by network configuration or device capability), then the possible set of repetition factors may be determined as M=2 (corresponding to chips of 16 samples, 8 μs) and M=4 (corresponding to chips of 8 samples, 4 μs). In another example, if the D2R bit duration is determined as 16 samples by the reader, only repletion factor M=1 (in other words, no repetition) can be supported since M=2 results in chip duration of 4 samples, 2 μs which cannot be supported by a device.

In another example solution, a reader may indicate the start of an inventory procedure with a transmission that includes one or more of: an R2D transmission preamble, R2D control information, an A-IoT procedure identifier (for example, the inventory procedure), time resources for the inventory procedure, and a time offset/period between the time resources for the inventory procedure. In an example, the time resources may be a number of ALOHA slots.

The R2D transmission preamble may include a start indicator part (SIP) indicating the beginning of a clock acquisition part (CAP). The CAP may be used by the device to measure the chip rate clock for R2D transmission.

The R2D control information may include configuration information for R2D data reception such as a time domain allocation for at least Msg. 0 of inventory procedure (time domain resource allocation (TDRA) for other R2D transmissions may be included as well). Also, the R2D control information may include configuration information for R2D data reception such as a chip rate and line coding configuration for at least Msg. 0 of inventory procedure (chip rate and line coding configuration for other R2D transmissions may be included as well). Further, the R2D control information may include configuration information for R2D data reception such as a slot format for, for example, slotted ALOHA random access procedure, i.e., number of slots, slot period, and the like.

Further, the R2D control information may include configuration information for D2R data transmission from a device for at least Msg. 1 transmission including a time domain allocation, a frequency allocation, available Msg. 1 identifiers for random access, and Msg. 1 format including additional fields, for example, device indication of energy level, device availability, and the like. The frequency allocation may be indicated by a frequency domain allocation indicator that could potentially refer to a configured/pre-configured/specified look up table for configuring possible values of one or more of: a baseband data chip rate; a line coding chip rate; and all possible chip rates for small frequency shift.

Further, the frequency allocation may be indicated by a frequency domain allocation indicator that could potentially refer to a scalar multiple, for example, n, used in a set of specified functions to determine D2R configuration such as provided below.

In one example method, a reader may indicate to a device a parameter n from which a device may determine a D2R duration, for example by measuring a R2D duration and scaling the measured duration with a function of the indicated parameter. In one example solution, the function may be 2⁻ⁿ. The determined D2R duration may be a D2R bit duration or the determined D2R duration may be a chip duration (e.g., a Manchester codeword chip). The determined duration may be referred to as a reference duration. The reference duration may be further divided, for example, divided into 2^{k} equal parts wherein k may take values n+1, n+2, . . . nₘₐₓ wherein each equal part may determine the smallest chip duration and the corresponding small frequency shift amount.

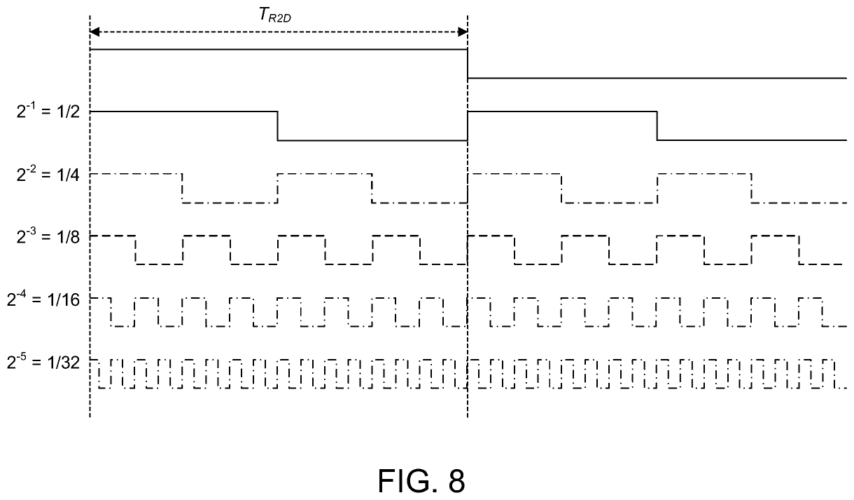

FIG. 8 is a transmission diagram illustrating an example of functional relations for D2R chip rate, line code rate, and small frequency shift rates as indicated in R2D control information. FIG. 8 shows a D2R baseband bit duration T_{D2R}=2⁻ⁿ. T_{R2D}, n∈{nₘᵢₙ, . . . , nₘₐₓ}, where T_{R2D} may be the chip duration measured by the device from the CAP of the R2D preamble. Note that the following may similarly apply, and still be consistent with the examples provided herein, if the T_{R2D} is a duration other than an R2D chip duration, for example if it is the duration of a Manchester codeword. The parameter n may be a scaling coefficient which may indicate a relationship between the durations of T_{R2D} and T_{D2R}. For example, if n is indicated to be 2 (i.e., n_{signaled}=2) and T_{D2R} indicates the duration of a D2R bit, then

$${T}_{D 2 R - bit} = \frac{1}{4} \cdot {T}_{R 2 D} .$$

Note that the following may similarly apply, and still be consistent with the examples provided herein, if the T_{D2R} is a duration other than a D2R bit duration, for example if it is the duration of a Manchester codeword chip.

In one example solution, the specific value of the parameter n (e.g., n=2) may be signaled, configured, indicated by the reader. The D2R duration computed by the device (e.g., by scaling a R2D duration with a function of n) may serve as a reference duration (e.g., a D2R bit or a D2R chip duration). The following may apply:

In one example solution, T_{D2R} may be the duration of a D2R bit. Then, the durations corresponding to 2⁻ⁿ. T_{R2D}, n∈{n_{signaled}, n_{signaled}+1, n_{signaled}+2, . . . , nₘₐₓ} may determine (respectively) a D2R bit duration, a chip duration of a Manchester codeword (e.g., M=1 and no frequency shift), ½ of the chip duration of a Manchester codeword (e.g., frequency shift corresponding to M=2), ¼ of the chip duration of a Manchester codeword (e.g., frequency shift corresponding to M=4), and so forth.

In FIG. 8,

$${n}_{signaled} = 2. Then , {T}_{D 2 R - bit} = \frac{1}{4} \cdot {T}_{R 2 D} and {T}_{Manchester chip} = \frac{1}{8} \cdot {T}_{R 2 D} ( M = 1 ) .$$

Supported chip durations for small frequency shift T_{FDM,i}=2-1. T_{D2R-bit}, i∈{1, . . . , nₘₐₓ−n_{signaled}} and i=1 corresponds to M=1, i=2 corresponds to M=2, and i=3 corresponds to M=4 (M=2ⁱ⁻¹⁾). A device may select of the available frequency shift values (e.g., M values) and generate the corresponding frequency shifted waveform, for example using one of the two methods disclosed previously. For example, for M=4, a device may either multiply Manchester codewords with a square wave of 4 cycles within a D2R bit duration or may repeat Manchester codewords 4 times within a D2R bit duration.

Further, FIG. 8 shows a line encoded chip duration (e.g., Manchester)

$${T}_{Manchester chip} = \frac{1}{2} {T}_{D 2 R} .$$

Supported chip durations for small frequency shift include T_{FDM,i}=2⁻ⁱ·T_{manchester chip}, i∈{1, . . . , nₘₐₓ−n_{signaled}}

Further: Nₘᵢₙ=2⁻ⁿ^{ₘₐₓ} and Nₘₐₓ=2⁻ⁿ^{ₘᵢₙ}, where Nₘᵢₙ and Nₘₐₓ are the minimum and maximum supported chip distances for T_{D2R}.

In another example solution, T_{D2R} may be the duration of a D2R chip. In this case, the methods disclosed herein similarly apply. For example, continuing the example above, if n is set to 2, then

$${T}_{Manchester chip} = \frac{1}{4} \cdot {T}_{R 2 D} .$$

Then, a reader may determine that there are 3 frequency shifts available corresponding to M=2, 4, and 8 and the chip durations for these frequency shifts may be determined as 2⁻ⁱ. T_{D2R chip}, i∈{1, . . . , nₘₐₓ−n}.

Additional parameters for chip rate determinations (i.e., (Nₘᵢₙ, Nₘₐₓ), non-multiple increases or decreases in chip rate for, for example, cyclin prefix (CP) handling, Tx/Rx switching, etc.) may be, for example, specified as constants, pre-configured during initial device configuration, configured during a write command from the reader WTRU, indicated explicitly by the reader as part of R2D control signaling, or indicated as device capability to the reader during initial device connection. Further, frequency domain allocation indications may be constant across all TDRAs configured for the WTRU.

Also, the R2D control information may include configuration information for a monitoring window for the device to receive a Msg.2 R2D random access response, including as an example: timing reference for the monitoring window; and start and duration of monitoring window relative to timing reference.

In a further step in the inventory procedure, the reader may transmit a Msg. 0 indicating the start of ALOHA slot such as, for example, a Query/QueryRep in RFID. Also, the reader may monitor TDRA and FDRA occasions for possible Msg. 1 transmissions assuming Msg. 1 configuration as indicated in the R2D control signaling.

If the reader successfully recovers a Msg 1 it may transmit a Msg. 2 random access response to the target device including an R2D transmission preamble, and R2D control information. The R2D transmission preamble may include the SIP indicating the beginning of a CAP, used by the device to measure the chip rate clock for R2D transmission.

The R2D control information may include configuration for R2D data reception, such as time domain allocation for at least Msg. 2 of inventory procedure (TDRA for other R2D transmissions may be included as well), and a chip rate and line coding configuration for at least Msg. 2 of inventory procedure (chip rate and line coding configuration for other R2D transmissions may be included as well).

Further, the R2D control information may include an indication of a Msg. 3 format, for example, read/write command, and the like.

Moreover, the R2D control information may include, if performing a read command, configuration for D2R data transmission from a device for at least Msg. 3 transmission including: time domain allocation for at least Msg. 3 of inventory procedure (TDRA for other R2D transmissions may be included as well); and a frequency domain allocation indicator as indicated for Msg. 1. Also, the frequency domain allocation for Msg. 3 may be indicated explicitly in Msg. 2, or implicitly using the indicated Msg. 1 FDRA either by default or if there is no explicit FDRA indication in Msg. 2.

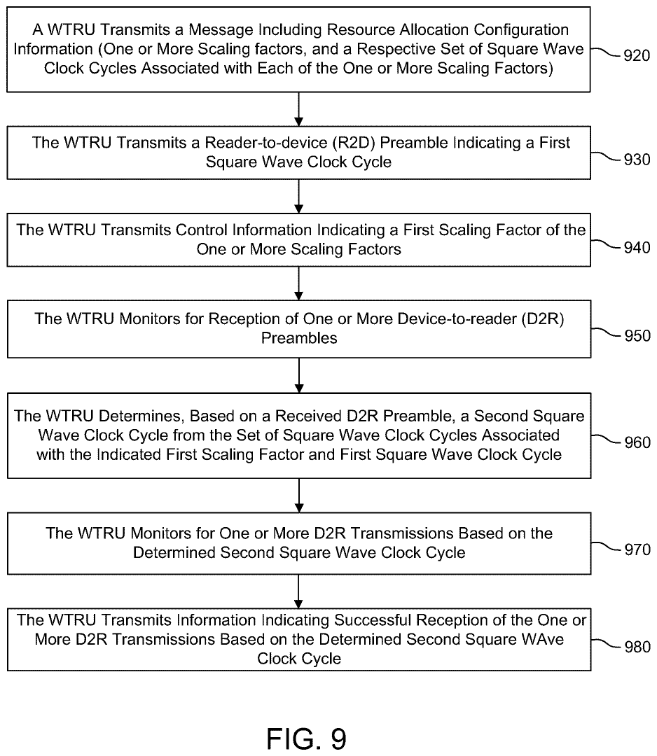

FIG. 9 is a flowchart diagram illustrating a procedure of frequency multiplexing with Manchester encoding. As shown in FIG. 9, a WTRU transmits a message including resource allocation configuration information. In an example, the resource allocation configuration information includes: one or more scaling factors, and a respective set of square wave clock cycles associated with each of the one or more scaling factors 920. Further, the WTRU transmits an R2D preamble indicating a first square wave clock cycle 930. Also, the WTRU transmits control information indicating a first scaling factor of the one or more scaling factors 940.

Further, the WTRU monitors for reception of one or more D2R preambles 950. Additionally, the WTRU determines, based on a received D2R preamble, a second square wave clock cycle from the set of square wave clock cycles associated with the indicated first scaling factor and first square wave clock cycle 960.

Also, the WTRU monitors for one or more D2R transmissions based on the determined second square wave clock cycle 970. Moreover, the WTRU transmits information indicating successful reception of the one or more D2R transmissions based on the determined second square wave clock cycle 980.

In an example, the second square wave clock cycle is a devise-selected second square wave clock cycle. Additionally or alternatively, the R2D preamble is transmitted to a device. Additionally or alternatively, the device is an AIoT device. Additionally or alternatively, the WTRU is a WTRU reader. Additionally or alternatively, the resource allocation configuration information further includes support for one or more types of frequency shifts.

Additionally or alternatively, a device-selected type of small frequency shift is determined based on the received D2R preamble. Additionally or alternatively, a number of times a device is expected to transmit or repeat a Manchester codeword in one bit duration is determined based on the number of clock cycle durations in a bit duration of a square wave clock cycle.

Additionally or alternatively, the monitoring for the one or more D2R transmissions is determined further based on a type of small frequency shift of the received D2R preamble. Additionally or alternatively, the resource allocation configuration information includes a second scaling factor of the one or more scaling factors.

Although features and elements are described above in particular combinations, one of ordinary skill in the art will appreciate that each feature or element can be used alone or in any combination with the other features and elements. In addition, the methods described herein may be implemented in a computer program, software, or firmware incorporated in a computer-readable medium for execution by a computer or processor. Examples of computer-readable media include electronic signals (transmitted over wired or wireless connections) and computer-readable storage media. Examples of computer-readable storage media include, but are not limited to, a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs). A processor in association with software may be used to implement a radio frequency transceiver for use in a WTRU, UE, terminal, base station, RNC, or any host computer.

What is claimed:

1. A method for use in a wireless transmit/receive unit (WTRU), the method comprising:
transmitting a message including resource allocation configuration information, wherein the resource allocation configuration information includes: one or more scaling factors, and a respective set of square wave clock cycles associated with each of the one or more scaling factors;
transmitting a reader-to-device (R2D) preamble indicating a first square wave clock cycle;
transmitting control information indicating a first scaling factor of the one or more scaling factors;
monitoring for reception of one or more device-to-reader (D2R) preambles;
determining, based on a received D2R preamble, a second square wave clock cycle from the set of square wave clock cycles associated with the indicated first scaling factor and first square wave clock cycle;
monitoring for one or more D2R transmissions based on the determined second square wave clock cycle; and
transmitting information indicating successful reception of the one or more D2R transmissions based on the determined second square wave clock cycle.

2. The method of claim 1, wherein the second square wave clock cycle is a devise-selected second square wave clock cycle.

3. The method of claim 1, wherein the R2D preamble is transmitted to a device.

4. The method of claim 3, wherein the device is an ambient Internet-of-Things (AIoT) device.

5. The method of claim 1, wherein the WTRU is a WTRU reader.

6. The method of claim 1, wherein the resource allocation configuration information further includes support for one or more types of frequency shifts.

7. The method of claim 1, wherein a device-selected type of small frequency shift is determined based on the received D2R preamble.

8. The method of claim 1, wherein a number of times a device is expected to transmit or repeat a Manchester codeword in one bit duration is determined based on the number of clock cycle durations in a bit duration of a square wave clock cycle.

9. The method of claim 1, wherein the monitoring for the one or more D2R transmissions is determined further based on a type of small frequency shift of the received D2R preamble.

10. The method of claim 1, wherein the resource allocation configuration information includes a second scaling factor of the one or more scaling factors.

11. A wireless transmit/receive unit (WTRU) comprising:
a transceiver; and
a processor, operatively coupled to a transceiver; wherein:
the transceiver and the processor are configured to transmit a message including resource allocation configuration information, wherein the resource allocation configuration information includes: one or more scaling factors, and a respective set of square wave clock cycles associated with each of the one or more scaling factors;
the transceiver and the processor are configured to transmit a reader-to-device (R2D) preamble indicating a first square wave clock cycle;
the transceiver and the processor are configured to transmit control information indicating a first scaling factor of the one or more scaling factors;
the transceiver and the processor are configured to monitor for reception of one or more device-to-reader (D2R) preambles;
the processor is configured to determine, based on a received D2R preamble, a second square wave clock cycle from the set of square wave clock cycles associated with the indicated first scaling factor and first square wave clock cycle;
the transceiver and the processor are configured to monitor for one or more D2R transmissions based on the determined second square wave clock cycle; and
the transceiver and the processor are configured to transmit information indicating successful reception of the one or more D2R transmissions based on the determined second square wave clock cycle.

12. The WTRU of claim 11, wherein the second square wave clock cycle is a devise-selected second square wave clock cycle.

13. The WTRU of claim 11, wherein the R2D preamble is transmitted to a device.

14. The WTRU of claim 13, wherein the device is an ambient Internet-of-Things (AIoT) device.

15. The WTRU of claim 11, wherein the WTRU is a WTRU reader.

16. The WTRU of claim 11, wherein the resource allocation configuration information further includes support for one or more types of frequency shifts.

17. The WTRU of claim 11, wherein a device-selected type of small frequency shift is determined based on the received D2R preamble.

18. The WTRU of claim 11, wherein a number of times a device is expected to transmit or repeat a Manchester codeword in one bit duration is determined based on the number of clock cycle durations in a bit duration of a square wave clock cycle.

19. The WTRU of claim 11, wherein the monitoring for the one or more D2R transmissions is determined further based on a type of small frequency shift of the received D2R preamble.

20. The WTRU of claim 11, wherein the resource allocation configuration information includes a second scaling factor of the one or more scaling factors.
